(19) United States
(12) Patent Application Publication
(10) Pub. No.: US 2026/0256021 A1
(43) Pub. Date: Aug. 27, 2026

(54) PACKAGE STRUCTURE AND METHOD OF FORMING THE SAME

(71) Applicant: Taiwan Semiconductor Manufacturing Company, Ltd., Hsinchu (TW)

(72) Inventors: Hung-Yu Chen, Hsinchu (TW); Pu Wang, Hsinchu City (TW); Li-Hui Cheng, New Taipei City (TW)

(73) Assignee: Taiwan Semiconductor Manufacturing Company, Ltd., Hsinchu (TW)

(21) Appl. No.: 19/062,059

(22) Filed: Feb. 25, 2025

(51) Int. Cl. H01L 23/04; H01L 21/48; H01L 21/56; H01L 23/00; H01L 23/18; H01L 23/31; H01L 23/538; H01L 25/16; H10B 80/00; H10D 80/30

(52) U.S. Cl. CPC H10W 76/12; H10W 70/093; H10W 74/01; H10W 74/131; H10W 76/42; H10W 90/00; H10B 80/00; H10D 80/30; H10W 70/611; H10W 70/65; H10W 72/823; H10W 74/15; H10W 90/401; H10W 90/724; H10W 90/734

(57) ABSTRACT

A package structure and a method of forming the same are provided. The package structure includes a package unit and passive components disposed on and electrically connected to a circuit substrate, a dam disposed on the circuit substrate and enclosing the package unit and the passive components, and an underfill disposed between the package unit and the circuit substrate. The passive components are laterally spaced apart from the package unit, and sandwiched between the dam and the package unit. The underfill extends from the package unit to the passive components, and extends from the passive components to the dam. An outer periphery of the underfill is in contact with the dam.

### BACKGROUND

In the field of semiconductor packaging, it is important to improve th stability of the package structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 6 are schematic cross-sectional views and top views of stages in a formation method of a package structure in accordance with some embodiments of the present disclosure.

FIG. 7 is a schematic cross-sectional view of a package structure in accordance with some embodiments of the present disclosure.

FIG. 8 is a schematic cross-sectional view of a package structure in accordance with some embodiments of the present disclosure.

FIG. 9 is a schematic cross-sectional view of a package structure in accordance with some embodiments of the present disclosure.

FIG. 10 is a schematic cross-sectional view of a package structure in accordance with some embodiments of the present disclosure.

FIG. 11 is a schematic cross-sectional view of a package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

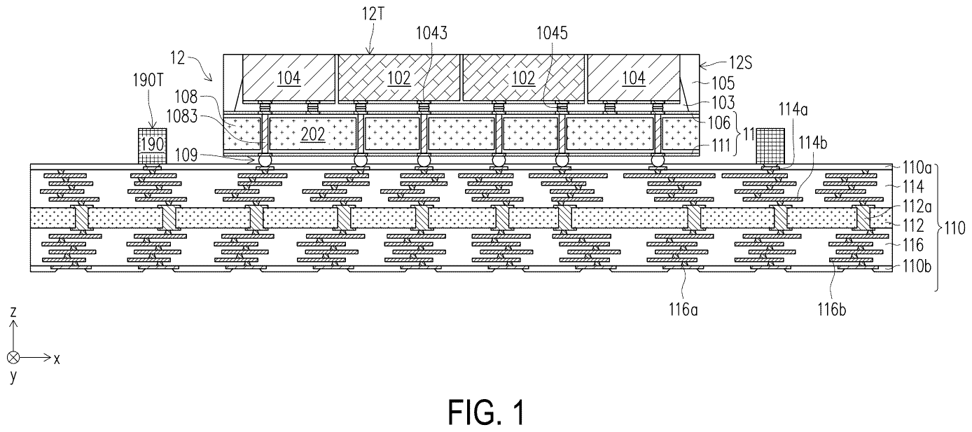

FIG. 1 to FIG. 6 are schematic cross-sectional views and top views of stages in a formation method of a package structure in accordance with some embodiments of the present disclosure.

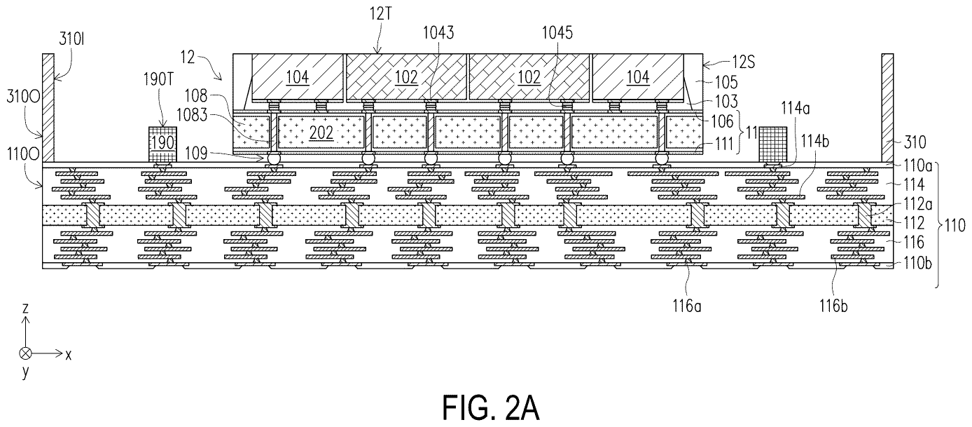

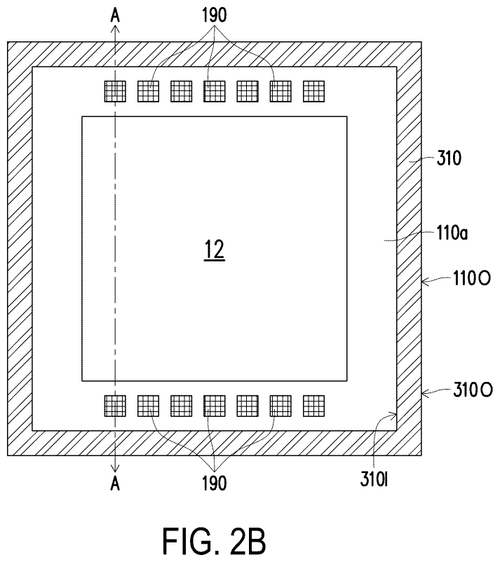

Referring to FIG. 1, one or more package units 12 (only one is shown) and passive components 190 are mounted onto and electrically connected to a circuit substrate 110 to form a semiconductor package. In some embodiments, the semiconductor package includes or is a chip-on-wafer-on-substrate (CoWoS) package, and the package unit 12 is bonded to and electrically connected with the circuit substrate 110 through electrical connectors 109. In other embodiments, the semiconductor package may be an integrated fan-out (InFO) package. In some embodiments, the electrical connectors 109 include or are controlled collapse chip connection (C4) bumps. In some embodiments, the passive components 190 include resistors, capacitors, inductors or the like. In some embodiments, the passive components 190 are attached to the circuit substrate 110 by surface mount technology (SMT). In some embodiments, the passive components 190 are disposed beside the package unit 12 and arranged in any suitable arrangement. In some embodiments, the passive components 190 are laterally spaced apart from the package unit 12, and surround at least one sidewall 12S of the package unit 12 (shown as FIG. 2B). In some embodiments, the passive components 190 include top surfaces 190T facing away from the circuit substrate 110.

In some embodiments, the circuit substrate 110 includes a core 112 penetrated by through vias 112a, and first and second redistribution structures disposed on opposite sides of the core 112 and electrically connected to each other by the through vias 112a. In some embodiments, the through vias 112a include metals, metal alloys, and/or other metal-containing compounds (e.g., Cu, Al, Mo, Co, Ru, W, TiN, TaN, WN, etc.).

In some embodiments, the first redistribution structure disposed on the core 112 includes an upper dielectric layer 114, a metal interconnect structure 114b formed in the upper dielectric layer 114, and contact pads 114a formed on the upper dielectric layer 114 and electrically connected to the metal interconnect structure 114b. For example, the upper dielectric layer 114 includes a build-up film (e.g., ABF), or an organic polymer material such as polyimide (PI), benzocyclobutene (BCB), or polybenzobisoxazole (PBO). For example, materials of the contact pads 114a and the metal interconnect structure 114b include conductive materials such as copper, aluminum, or other suitable materials.

In some embodiments, a passivation layer 110a (referred as a solder mask or a solder resist layer) is formed on the upper dielectric layer 114 and reveals the contact pads 114a. For example, the passivation layer 110a includes silicon oxide, silicon nitride, low-k dielectric materials such as carbon-doped oxides, extremely low-k dielectric materials such as porous carbon doped silicon dioxide, a combination thereof or other suitable material. In some embodiments, the package unit 12 is bonded to and electrically connected with the contact pads 114a of the circuit substrate 110 through electrical connectors 109. In some embodiments, the passive components 190 are bonded to the contact pads 114a of the circuit substrate 110.

In some embodiments, the second redistribution structure is disposed on the core 112 opposite to the first redistribution structure, and includes a lower dielectric layer 116, a metal interconnect structure 116b formed in the lower dielectric layer 116, and contact pads 116a formed on the lower dielectric layer 116 and electrically connected to the metal interconnect structure 116b. In some embodiments, the material of the lower dielectric layer 116 is the same as the upper dielectric layer 114, and the materials of the contact pads 116a and the metal interconnect structure 116b are the same as the contact pads 114a and the metal interconnect structure 114b, respectively. In some embodiments, a passivation layer 110b is formed on the lower dielectric layer 116 and reveals the contact pads 116a for connecting subsequently formed connective terminals 25. In some embodiments, the material of the passivation layer 110b is the same as the passivation layer 110a.

In some embodiments, the package unit 12 includes four semiconductor dies or more, and two semiconductor dies 102 and two semiconductor dies 104 are shown in the cross-sectional view of the figure as an example. In some embodiments, the semiconductor dies 102, 104 may independently be or include a logic die, such as a central processing unit (CPU) die, a graphic processing unit (GPU) die, a micro control unit (MCU) die, an input-output (I/O) die, a baseband (BB) die, a system-on-chip (SoC) die, a large-scale integrated circuit (LSI) die, or an application processor (AP) die. In some embodiments, the semiconductor dies 102 include or are SoC dies and the semiconductor dies 104 include or are HBM dies. The disclosure is not limited by the types of dies included in the package unit 12.

In some embodiments, the semiconductor dies 102, 104 are disposed with active surfaces facing an interposer 11, and are bonded to a first redistribution layer 106 of the interposer 11. In some embodiments, the semiconductor dies 102, 104 are electrically connected to the first redistribution layer 106 of the interposer 11. In some embodiments, contact pads 1043 of the semiconductor dies 102, 104 are bonded to contact pads of the first redistribution layer 106 through micro-connectors 1045.

In some embodiments, the interposer 11 includes a molding layer 108, through semiconductor vias (TSVs) 1083 penetrating the molding layer 108 for dual-side electrical connection, the first redistribution layer 106 disposed on a first surface of the molding layer 108, and a second redistribution layer 111 disposed on a second surface of the molding layer 108. The second surface of the molding layer 108 is opposite to the first surface of the molding layer 108. The second redistribution layer 111 includes contact pads bonded to the contact pads 114a of the circuit substrate 110 through the electrical connectors 109. In some embodiments, a material of the TSVs 1083 includes one or more metal material such as copper, titanium, tungsten, aluminum, combinations thereof, or the like. In some embodiments, the TSVs 1083, the semiconductor dies 102, 104 are electrically connected to the circuit substrate 110 through the electrical connectors 109 located between the interposer 11 and the circuit substrate 110. In other embodiments, the interposer 11 includes a silicon interposer.

In some embodiments, after the semiconductor dies 102, 104 are bonded to the first redistribution layer 106, an underfill 103 is formed between the semiconductor dies 102, 104 and the first redistribution layer 106 and surrounds the micro-connectors 1045 to protect the micro-connectors 1045 against thermal or physical stresses and secure the electrical connection of the semiconductor dies 102, 104 to the interposer 11. In some embodiments, the underfill 103 is formed by capillary underfill filling (CUF). In some embodiments, as shown in FIG. 1, the underfill 103 is formed into multiple underfill portions with each portion respectively securing the semiconductor die 102 or 104 and the corresponding micro-connectors 1045. In some alternative embodiments, a single common underfill (not shown) may extend below the semiconductor dies 102, 104, depending on the spacing and relative positions of the dies over the interposer.

In some embodiments, an encapsulant 105 is formed over the first redistribution layer 106 of the interposer 11, wraps the semiconductor dies 102, 104, and wraps the underfill 103. In some embodiments, the encapsulant 105 laterally encapsulates the semiconductor dies 102, 104 and reveals backside surfaces of the semiconductor dies 102, 104. In some embodiments, the encapsulant 105 includes a molding compound, a resin (such as epoxy resin or phenolic resin), or the like.

In FIG. 1, only one package unit 12 with three semiconductor dies 102, 104 are shown on the interposer 11 for simplicity, but the disclosure is not limited thereto. In some embodiments, the package unit 12 includes a top surface 12T facing away from the interposer 11, and sidewalls 12S around the top surface 12T of the package unit 12. In some embodiments, the top surface 12T of the package unit 12 includes the revealed backside surface of the semiconductor dies 102, 104, and a top surface of the encapsulant 105 levelled with the revealed backside surface of the semiconductor dies 102, 104. In some embodiments, the sidewalls 12S of the package unit 12 includes sidewalls of the encapsulant 105, and sidewalls of the interposer 11. Furthermore, whilst the process is currently being illustrated for a chip-on-wafer-on-substrate (CoWoS) package, the disclosure is not limited to the package structure shown in the drawings.

Referring to FIG. 2A and FIG. 2B, FIG. 2B is a top view, and FIG. 2A is a cross-sectional view along a line A-A in FIG. 2B. In some embodiments, a dam 310 is formed on the passivation layer 110a of the circuit substrate 110, and encloses the package unit 12 and the passive components 190. In some embodiments, the passive components 190 are sandwiched between the dam 310 and the package unit 12. In some embodiments, the dam 310 forms a continuous frame wall following the profile of an outer periphery 110O of the circuit substrate 110. The continuous frame wall encloses the package unit 12 and the passive components 190, and is spaced apart from the package unit 12 and the passive components 190. In some embodiments, an outer sidewall 310O of the dam 310 may be aligned with the outer periphery 110O of the circuit substrate 110. In some embodiments, an inner sidewall 310I of the dam 310 is opposite to the outer sidewall 310O of the dam 310, and faces to the passive components 190 and the package unit 12. In some embodiments, the dam 310 may be shaped as a rectangle wall in FIG. 2B.

In some embodiments, the dam 310 functions as a blockage dam for preventing the outflow of subsequently formed underfill 320. In some embodiments, the dam 310 has a height substantially equal to a height of the package unit 12. In some embodiments, the dam 310 has a height higher than a height of the package unit 12. For example, a material of the dam 310 includes a thermo-curable material such as a thermo-curable resin. In some embodiments, the dam 310 is made from a polymeric dielectric material such as epoxy resins, silicon-containing resins or acrylic resins. In some embodiments, the dam 310 may be formed by a dispensing process and a cure process.

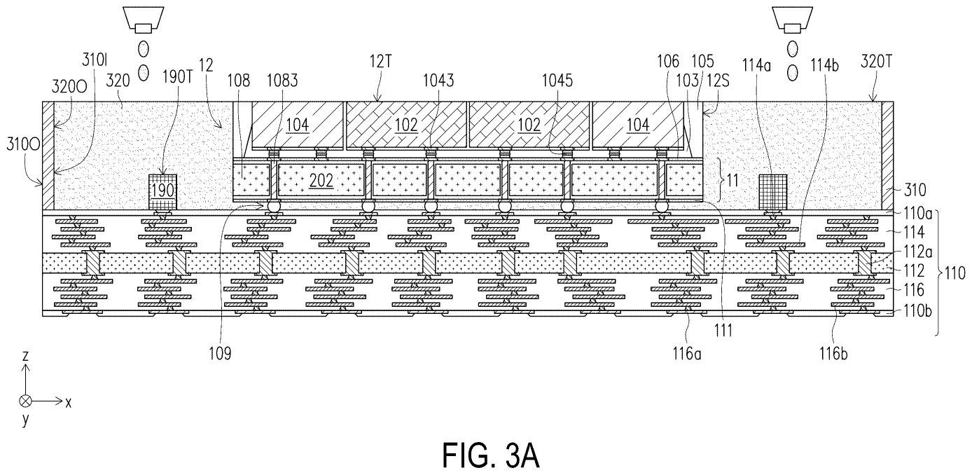

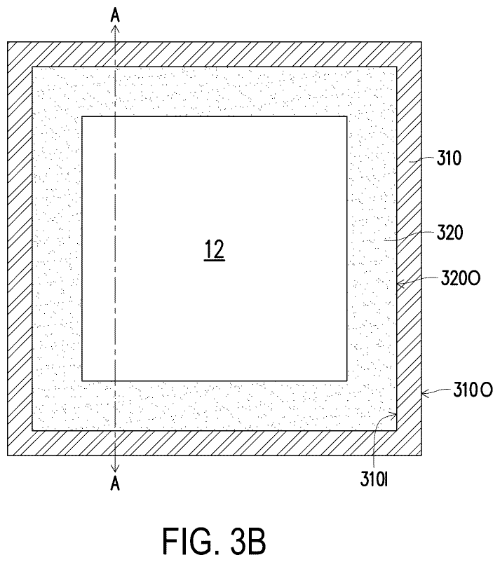

Referring to FIG. 3A and FIG. 3B, FIG. 3B is a top view, and FIG. 3A is a cross-sectional view along a line A-A in FIG. 3B. In some embodiments, the underfill 320 is applied to spaces between the dam 310 and the package unit 12, and between the package unit 12 and the passivation layer 110a of the circuit substrate 110. In some embodiments, the dam 310 has a height higher than or equal to a height of the underfill 320 for preventing the outflow of the underfill 320.

In some embodiments, the underfill 320 covers the top surfaces 190T of the passive components 190 and surrounds the passive components 190. In some embodiments, the passive components 190 are disposed within the underfill 320. In some embodiments, the passive components 190 are surrounded by the underfill 320 and embedded in the underfill 320 to protect the passive components 190 from mechanical stresses and secure the passive components 190. In some embodiments, the underfill 320 is disposed between the package unit 12 and the circuit substrate 110 to protect the electrical connectors 109 from thermal and mechanical stresses and secure the package unit 12.

In some embodiments, the underfill 320 extends from the inner sidewall 310I of the dam 310 to the sidewalls 12S of the package unit 12. In some embodiments, the underfill 320 extends from the package unit 12 to the passive components 190, and extends from the passive components 190 to the dam 310. In some embodiments, an outer periphery 320O of the underfill 320 is in contact with the inner sidewall 310I of the dam 310. In some embodiments, the underfill 320 surrounding the overall sidewalls 12S of the package unit 12 and covering approximately overall surface of the passivation layer 110a of the circuit substrate 110 may function as a stress buffer for preventing the crack between the package unit 12 and the circuit substrate 110.

In some embodiments, a top surface 320T of the underfill 320 is higher than the top surfaces 190T of the passive components 190, and the underfill 320 covers the top surfaces 190T of the passive components 190. In some embodiments, the top surface 320T of the underfill 320 is substantially levelled with the top surface 12T of the package unit 12, and the top surface 12T of the package unit 12 is revealed from the underfill 320. In some embodiments, the top surface 320T of the underfill 320 and the top surface 12T of the package unit 12 are higher than the top surfaces 190T of the passive components 190. In some embodiments, the underfill 320 encloses and is in contact with the package unit 12. In some embodiments, the dam 310 encloses the underfill 320, and the inner sidewall 310I of the dam 310 is covered by the underfill 320.

For example, a material of the underfill 320 includes a resin material such as an epoxy resin material. In some embodiments, the underfill 320 may include a filler such as silicon oxide, aluminum oxide, diamond powder, silver material, copper material or the like. In some embodiments, the underfill 320 has the filler in a range from about 40% to about 70%. In some embodiments, the underfill 320 is formed by capillary underfill filling (CUF) and then cured.

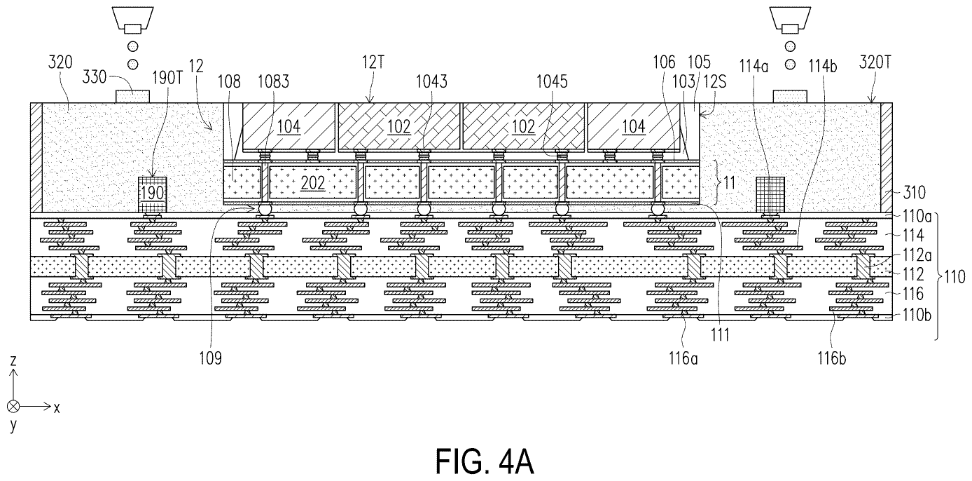

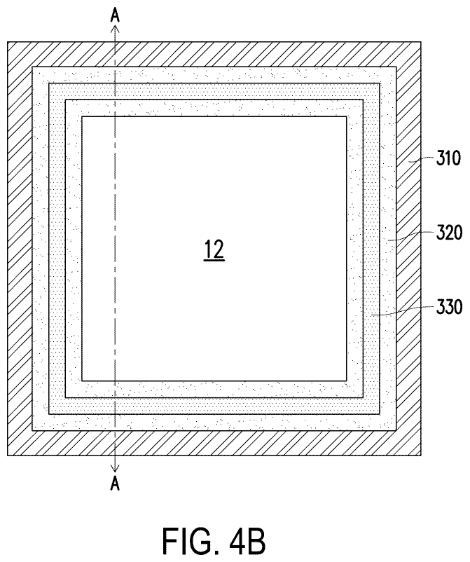

Referring to FIG. 4A and FIG. 4B, FIG. 4B is a top view, and FIG. 4A is a cross-sectional view along a line A-A in FIG. 4B. In some embodiments, an adhesive 330 is applied on the top surface 320T of the underfill 320 and surrounds the package unit 12. In some embodiments, the adhesive 330 encloses the package unit 12, and is disposed between the dam 310 and the package unit 12. In some embodiments, a material of the adhesive 330 includes a thermo-curable adhesive, a photocurable adhesive, a thermally conductive adhesive, a thermosetting resin, a waterproof adhesive, a lamination adhesive, or a combination thereof. According to the type of material(s) used, the adhesive 330 may be formed by dispensing, lamination, printing, or any other suitable technique. In some embodiments, the adhesive 330 and the dam 310 may be formed from the same material. In FIG. 4B, the dam 310 encloses the adhesive 330, and the adhesive 330 encloses the package unit 12.

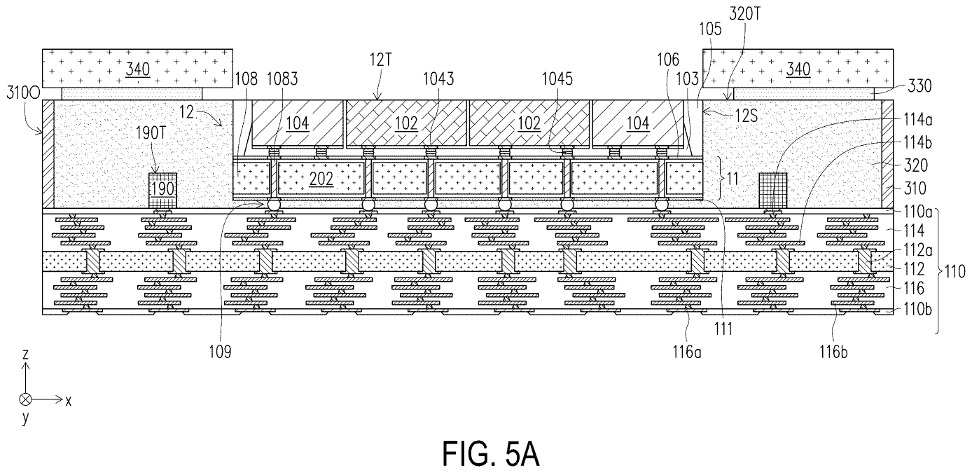

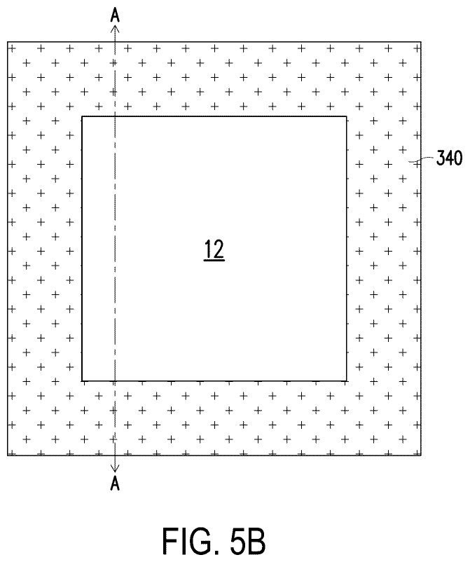

Referring to FIG. 5A and FIG. 5B, FIG. 5B is a top view, and FIG. 5A is a cross-sectional view along a line A-A in FIG. 5B. In some embodiments, a fastening ring structure 340 is mounted to the circuit substrate 110. In some embodiments, the fastening ring structure 340 is adhered to the circuit substrate 110 through the underfill 320 and the adhesive 330, and surrounds the package unit 12. In some embodiments, the fastening ring structure 340 is disposed above the passive components 190. In some embodiments, the fastening ring structure 340 forms a continuous frame wall on the adhesive 330 and the underfill 320. The continuous frame wall surrounds the package unit 12. For example, the fastening ring structure 340 includes metals and/or metal alloys such as Al, Cu, Ni, Co, combinations thereof, and the like.

In some embodiments, the fastening ring structure 340 is provided to be a basement of the cooling system. A foot dimension of the fastening ring structure 340 is related to the mechanical support property (such as the rigidity) of the fastening ring structure 340. The greater foot dimension of the fastening ring structure 340 has the better ability for easing the warpage of the circuit substrate 110. In some embodiments, a foot dimension of the fastening ring structure 340 disposed on the underfill 320 and above the passive components 190 may have better extension than a foot dimension of the fastening ring structure disposed on the outer periphery of the circuit substrate 110 and beside the passive components 190 due to the limitation of the layout of the passive components 190. For example, an extension of the foot dimension of the fastening ring structure 340 may be maximized (e.g. the foot dimension of the fastening ring structure 340 extends from an outer periphery aligned with the outer sidewall 310O of the dam 310 to an inner periphery aligned with the sidewalls 12S of the package unit 12. Therefore, the fastening ring structure 340 landing on the underfill 320 has better and greater foot dimension to counterbalance and lessen the warpage of the circuit substrate 110.

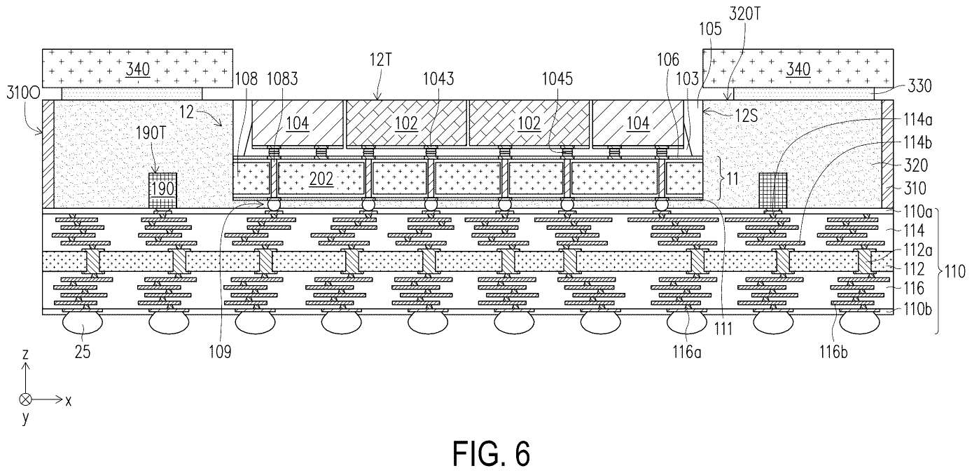

Referring to FIG. 6, the connective terminals 25 are formed on the contact pads 116a of the circuit substrate 110 for further electrical connection. In some embodiments, the connective terminals 25 are solder balls for ball grid array (BGA) mounts. In some embodiments, the connective terminals 25 are electrically connected to the package unit 12 through the circuit substrate 110. In some embodiments, electrical devices may be disposed on and electrically connected to the contact pads 116a of the circuit substrate 110 and beside the connective terminals 25 through surface mount technology (SMT).

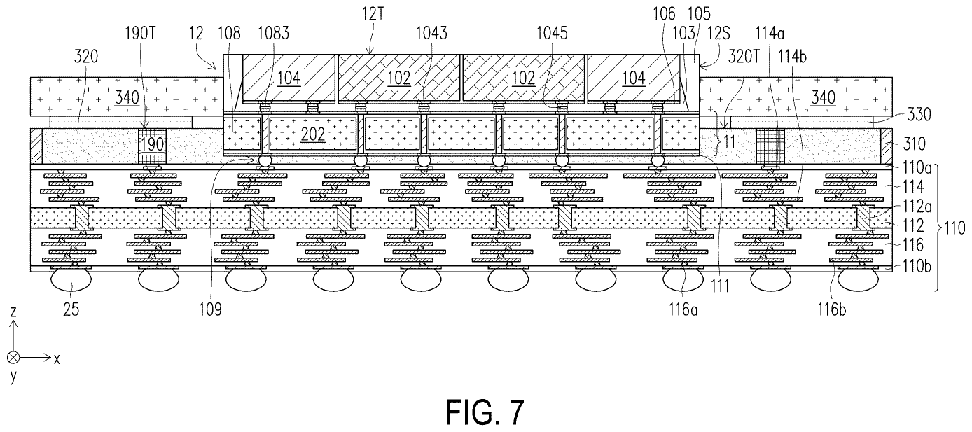

FIG. 7 is a schematic cross-sectional view of a package structure in accordance with some embodiments of the present disclosure. Except for the further description, the definition of the reference symbols and labeled representations are the same as FIG. 1 through FIG. 6, and will not be repeated herein.

Referring to FIG. 7, the difference from FIG. 6 is that the top surface 320T of the underfill 320 is substantially levelled with the top surfaces 190T of the passive components 190, and the top surfaces 190T of the passive components 190 are revealed from the underfill 320. In some embodiments, the adhesive 330 is applied on the top surface 320T of the underfill 320, is applied on the top surfaces 190T of the passive components 190, and surrounds the package unit 12. In some embodiments, the adhesive 330 is in contact with the top surface 320T of the underfill 320, and the top surfaces 190T of the passive components 190. In some embodiments, the fastening ring structure 340 is adhered to the circuit substrate 110 through the underfill 320 and the adhesive 330. In some embodiments, the fastening ring structure 340 surrounds the package unit 12. In FIG. 7, a top surface of the fastening ring structure 340 is lower than the top surface 12T of the package unit 12, but the disclosure is not limited thereto. In FIG. 7, the fastening ring structure 340 is in contact with the sidewalls 12S of the package unit 12, but the disclosure is not limited thereto. In some embodiments, the fastening ring structure 340 is laterally spaced apart from the package unit 12.

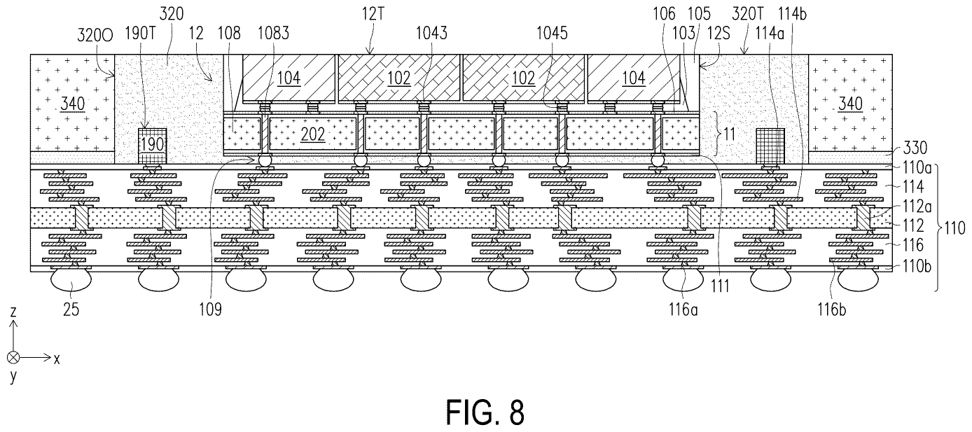

FIG. 8 is a schematic cross-sectional view of a package structure in accordance with some embodiments of the present disclosure. Except for the further description, the definition of the reference symbols and labeled representations are the same as FIG. 1 through FIG. 6, and will not be repeated herein.

Referring to FIG. 8, the difference from FIG. 6 is that the adhesive 330 and the fastening ring structure 340 function as a blockage dam for preventing the outflow of the underfill 320. In some embodiments, the adhesive 330 and the fastening ring structure 340 are formed before the underfill 320 is formed. In some embodiments, the adhesive 330 is applied on the circuit substrate 110 by following the profile of the outer periphery 110O of the circuit substrate 110. In some embodiments, the adhesive 330 is applied on the passivation layer 110a of the circuit substrate 110 and surrounds the passive components 190 and the package unit 12. In some embodiments, the passive components 190 are disposed between the adhesive 330 and the package unit 12.

In some embodiments, the fastening ring structure 340 is mounted to the circuit substrate 110. In some embodiments, the fastening ring structure 340 is adhered to the circuit substrate 110 through the adhesive 330, and encloses the passive components 190 and the package unit 12. In some embodiments, the fastening ring structure 340 is disposed beside and laterally spaced apart from the passive components 190. In some embodiments, the fastening ring structure 340 forms a continuous frame wall on the adhesive 330, and surrounds the passive components 190 and the package unit 12.

In some embodiments, the passive components 190 are surrounded by the underfill 320 to protect the passive components 190 from mechanical stresses and secure the passive components 190. In some embodiments, the underfill 320 is disposed between the package unit 12 and the circuit substrate 110 to protect the electrical connectors 109 from thermal and mechanical stresses and secure the package unit 12.

In some embodiments, the dam includes the adhesive 330 disposed on the circuit substrate 110, and the fastening ring structure 340 adhered to the circuit substrate 110 through the adhesive 330 and enclosing the passive components 190 and the package unit 12. In some embodiments, the underfill 320 is applied to spaces between the dam and the package unit 12, and between the package unit 12 and the passivation layer 110a of the circuit substrate 110, after the fastening ring structure 340 is mounted to the circuit substrate 110.

In some embodiments, the underfill 320 extends from an inner sidewall of the dam to the sidewalls 12S of the package unit 12. In some embodiments, the underfill 320 extends from the package unit 12 to the passive components 190, and extends from the passive components 190 to the dam. In some embodiments, the outer periphery 320O of the underfill 320 is in contact with the inner sidewall of the dam (e.g. the adhesive 330 and the fastening ring structure 340). In some embodiments, a sum of a height of the adhesive 330 and a height of the fastening ring structure 340 is substantially equal to a height of the package unit 12. In some embodiments, the underfill 320 surrounding the overall sidewalls 12S of the package unit 12 and covering approximately overall surface of the passivation layer 110a of the circuit substrate 110 may function as a stress buffer for preventing the crack between the package unit 12 and the circuit substrate 110.

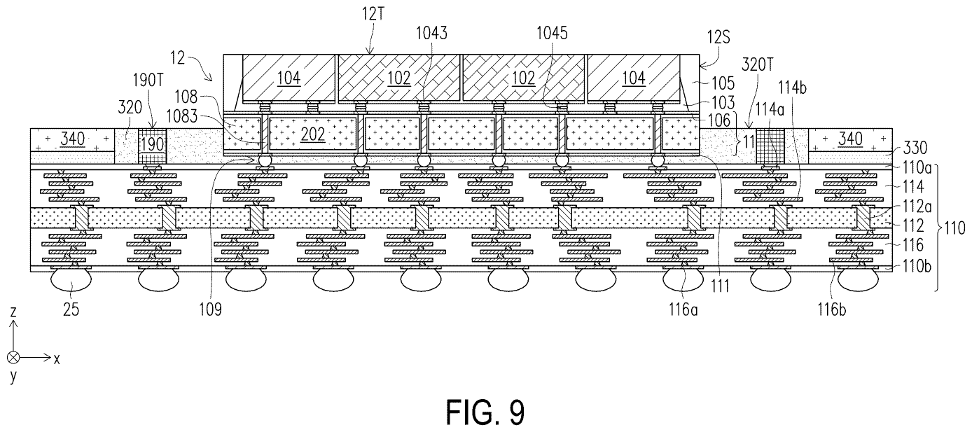

FIG. 9 is a schematic cross-sectional view of a package structure in accordance with some embodiments of the present disclosure. Except for the further description, the definition of the reference symbols and labeled representations are the same as FIG. 8, and will not be repeated herein.

Referring to FIG. 9, the difference from FIG. 8 is that the top surface 320T of the underfill 320 is substantially levelled with the top surfaces 190T of the passive components 190, and the top surfaces 190T of the passive components 190 are revealed from the underfill 320. In FIG. 9, a top surface of the fastening ring structure 340 is lower than the top surface 12T of the package unit 12, but the disclosure is not limited thereto. In some embodiments, a sum of a height of the adhesive 330 and a height of the fastening ring structure 340 is substantially equal to heights of the passive components 190.

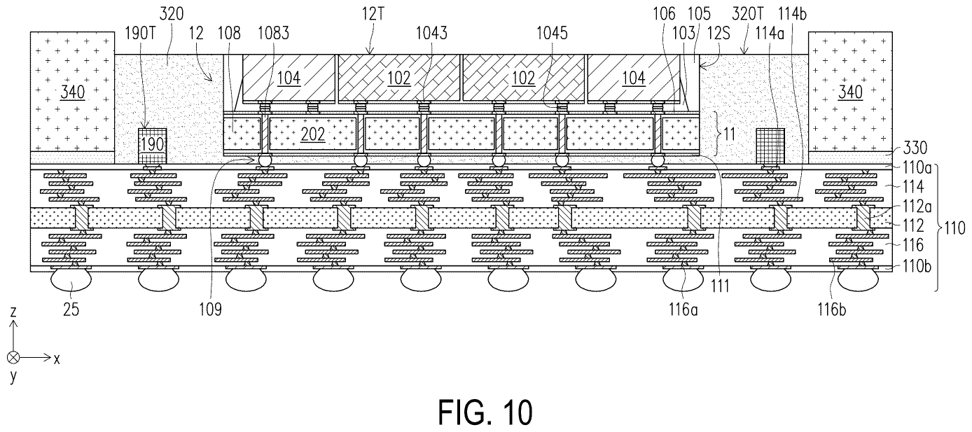

FIG. 10 is a schematic cross-sectional view of a package structure in accordance with some embodiments of the present disclosure. Except for the further description, the definition of the reference symbols and labeled representations are the same as FIG. 8, and will not be repeated herein.

Referring to FIG. 10, the difference from FIG. 8 is that a sum of a height of the adhesive 330 and a height of the fastening ring structure 340 is higher than a height of the package unit 12 or/and a height of the underfill 320. In some embodiments, a top surface of the fastening ring structure 340 is higher than the top surface 12T of the package unit 12 and the top surface 320T of the underfill 320.

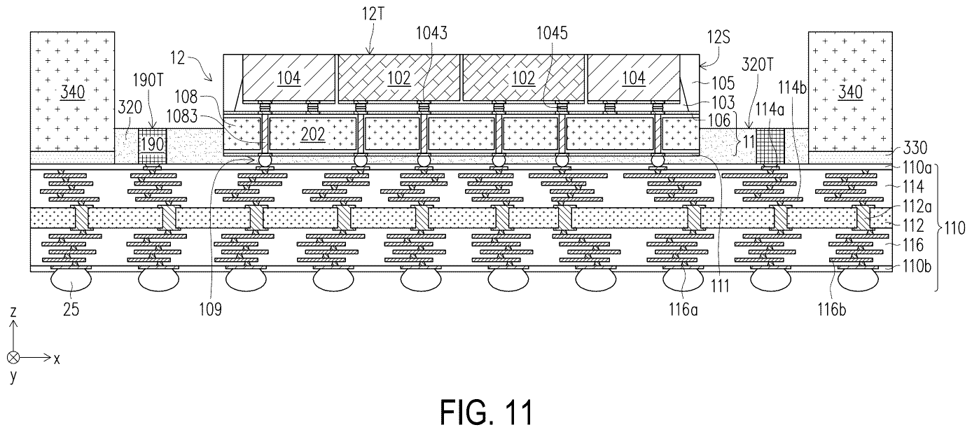

FIG. 11 is a schematic cross-sectional view of a package structure in accordance with some embodiments of the present disclosure. Except for the further description, the definition of the reference symbols and labeled representations are the same as FIG. 10, and will not be repeated herein.

Referring to FIG. 11, the difference from FIG. 10 is that the top surface 320T of the underfill 320 is substantially levelled with the top surfaces 190T of the passive components 190, and the top surfaces 190T of the passive components 190 are revealed from the underfill 320. In FIG. 11, a sum of a height of the adhesive 330 and a height of the fastening ring structure 340 is higher than a height of the package unit 12. In some embodiments, a top surface of the fastening ring structure 340 is higher than the top surface 12T of the package unit 12.

In accordance with some embodiments of the present disclosure, a package structure is provided. The package structure includes a package unit and passive components disposed on and electrically connected to a circuit substrate, a dam disposed on the circuit substrate and enclosing the package unit and the passive components, and an underfill disposed between the package unit and the circuit substrate. The passive components are laterally spaced apart from the package unit, and sandwiched between the dam and the package unit. The underfill extends from the package unit to the passive components, and extends from the passive components to the dam. An outer periphery of the underfill is in contact with the dam.

In accordance with some embodiments of the present disclosure, a package structure is provided. The package structure includes a package unit disposed on and electrically connected to the circuit substrate, a dam disposed on an outer periphery of the circuit substrate, an underfill disposed between the package unit and the circuit substrate and extending from an inner sidewall of the dam to sidewalls of the package unit, and passive components disposed within the underfill. The dam includes a continuous frame wall to enclose the package unit. The passive components are sandwiched between the dam and the package unit and electrically connected to the circuit substrate.

In accordance with some embodiments of the present disclosure, a method of forming a package structure is provided. A package unit is formed on a circuit substrate. Passive components are formed on the circuit substrate and laterally spaced apart from the package unit. A dam is formed on the circuit substrate. The dam encloses the package unit and the passive components. The passive components are sandwiched between the dam and the package unit. An underfill is applied a to a space between the dam and the package unit. The underfill is disposed between the package unit and the circuit substrate, extends from the package unit to the passive components, and extends from the passive components to the dam. An outer periphery of the underfill is in contact with the dam.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a circuit substrate,
a package unit disposed on and electrically connected to the circuit substrate;
passive components disposed on and electrically connected to the circuit substrate, and laterally spaced apart from the package unit;
a dam disposed on the circuit substrate, and enclosing the package unit and the passive components, wherein the passive components are sandwiched between the dam and the package unit; and
an underfill disposed between the package unit and the circuit substrate, extending from the package unit to the passive components, and extending from the passive components to the dam, wherein an outer periphery of the underfill is in contact with the dam.

2. The package structure of claim 1, wherein a top surface of the underfill is higher than top surfaces of the passive components, and the underfill covers the top surfaces of the passive components.

3. The package structure of claim 2, wherein the top surface of the underfill is substantially levelled with a top surface of the package unit, and the top surface of the package unit is revealed from the underfill.

4. The package structure of claim 1, wherein a top surface of the underfill is substantially levelled with top surfaces of the passive components, and the top surfaces of the passive components are revealed from the underfill.

5. The package structure of claim 1, further comprising:
an adhesive disposed on a top surface of the underfill; and
a fastening ring structure adhered to the underfill through the adhesive, surrounding the package unit, and disposed above the passive components.

6. The package structure of claim 1, wherein the dam further comprises:
an adhesive disposed on the circuit substrate; and
a fastening ring structure adhered to the circuit substrate through the adhesive, and enclosing the package unit.

7. The package structure of claim 6, wherein the outer periphery of the underfill is in contact with the adhesive and the fastening ring structure.

8. The package structure of claim 1, wherein the dam has a height higher than or equal to a height of the underfill.

9. A package structure, comprising:
a circuit substrate,
a package unit disposed on and electrically connected to the circuit substrate;
a dam disposed on an outer periphery of the circuit substrate, and comprising a continuous frame wall to enclose the package unit;
an underfill disposed between the package unit and the circuit substrate, and extending from an inner sidewall of the dam to sidewalls of the package unit; and
passive components disposed within the underfill, sandwiched between the dam and the package unit, and electrically connected to the circuit substrate.

10. The package structure of claim 9, wherein a top surface of the underfill is higher than top surfaces of the passive components, and the underfill covers the top surfaces of the passive components.

11. The package structure of claim 10, wherein the top surface of the underfill is substantially levelled with a top surface of the package unit, and the top surface of the package unit is revealed from the underfill.

12. The package structure of claim 9, wherein a top surface of the underfill is substantially levelled with top surfaces of the passive components, and the top surfaces of the passive components are revealed from the underfill.

13. The package structure of claim 9, further comprising:
an adhesive disposed on a top surface of the underfill; and
a fastening ring structure adhered to the underfill through the adhesive, surrounding the package unit, and disposed above the passive components.

14. The package structure of claim 9, wherein the dam further comprises:
an adhesive disposed on the outer periphery of the circuit substrate; and
a fastening ring structure adhered to the circuit substrate through the adhesive, and enclosing the package unit.

15. The package structure of claim 14, wherein an outer periphery of the underfill is in contact with the adhesive and the fastening ring structure.

16. A method of forming a package structure, comprising:
forming a package unit on a circuit substrate;
forming passive components on the circuit substrate and laterally spaced apart from the package unit;
forming a dam on the circuit substrate, wherein the dam encloses the package unit and the passive components and the passive components are sandwiched between the dam and the package unit; and
applying an underfill to a space between the dam and the package unit, wherein the underfill is disposed between the package unit and the circuit substrate, extends from the package unit to the passive components, and extends from the passive components to the dam, and wherein an outer periphery of the underfill is in contact with the dam.

17. The method of claim 16, wherein a top surface of the underfill is higher than top surfaces of the passive components, and the underfill covers the top surfaces of the passive components.

18. The method of claim 16, wherein a top surface of the underfill is substantially levelled with top surfaces of the passive components, and the top surfaces of the passive components are revealed from the underfill.

19. The method of claim 16, further comprising:
applying an adhesive on a top surface of the underfill; and
mounting a fastening ring structure to the underfill through the adhesive, wherein the fastening ring structure surrounds the package unit, and is disposed on the passive components.

20. The method of claim 16, wherein forming the dam further comprises:
applying an adhesive on an outer periphery of the circuit substrate; and
mounting a fastening ring structure to the circuit substrate through the adhesive, wherein the fastening ring structure encloses the package unit.
